(19) United States
(12) Patent Application Publication
(10) Pub. No.: US 2024/0176234 A1
(43) Pub. Date: May 30, 2024

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Sangkyun IM, Suwon-si (KR); Seungyong CHAE, Suwon-si (KR); Yaeun SEO, Suwon-si (KR); Taegeun SEONG, Suwon-si (KR); Minyoung LEE, Suwon-si (KR); Jimin KIM, Suwon-si (KR)

(21) Appl. No.: 18/484,247

(22) Filed: Oct. 10, 2023

(30) Foreign Application Priority Data
Nov. 16, 2022 (KR) 10-2022-0153722

(51) Int. Cl. G03F 7/004; C07F 7/22

(52) U.S. Cl. CPC G03F 7/0042; C07F 7/2224

(57) ABSTRACT

A semiconductor photoresist composition includes an organotin compound represented by Chemical Formula 1 and a solvent. A method for forming patterns uses the semiconductor photoresist composition.

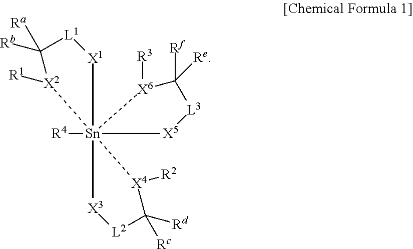

### CROSS-REFERENCE TO RELATED APPLICATION

This application claims priority to and the benefit of Korean Patent Application No. 10-2022-0153722, filed in the Korean Intellectual Property Office on Nov. 16, 2022, the entire content of which is incorporated herein by reference.

### BACKGROUND

### 1. Field

This disclosure relates to a semiconductor photoresist composition and a method for forming patterns utilizing the same.

### 2. Description of the Related Art

Extreme ultraviolet (EUV) lithography has gained attention as an important (e.g., essential) technology for manufacturing a next generation semiconductor device. The EUV lithography is a pattern-forming technology utilizing an EUV ray having a wavelength of about 13.5 nm as an exposure light source. According to the EUV lithography, an extremely fine pattern (e.g., less than or equal to about 20 nm) may be formed through an exposure process during the manufacture of a semiconductor device.

The extreme ultraviolet (EUV) lithography is realized through development of compatible photoresists which can be performed at a spatial resolution of less than or equal to about 16 nm. Currently, efforts to overcome insufficient specifications of related art chemically amplified (CA) photoresists, such as resolution, photospeed, and/or feature roughness (or also referred to as a line edge roughness or LER), for the next generation device are being made.

An intrinsic image blurring due to an acid catalyzed reaction in these polymer-type or kind photoresists limits the resolution in small feature sizes, which has been known in electron beam (e-beam) lithography for a long time. The chemically amplified (CA) photoresists are designed for high sensitivity, but because their typical elemental makeups reduce light absorbance of the photoresists at a wavelength of about 13.5 nm and thus decrease their sensitivity, the chemically amplified (CA) photoresists may (e.g., partially) have more difficulties under an EUV exposure.

The CA photoresists may have difficulties in the small feature sizes due to roughness issues, and have increased line edge roughness (LER), as the photospeed is decreased partially due to an inherited characteristics (e.g., an essence) of acid catalyst processes. Accordingly, a novel high-performance photoresist is desired (e.g., required) in the semiconductor industry because of these defects and problems of the CA photoresists.

In order to overcome the aforementioned drawbacks of the chemically amplified (CA) organic photosensitive composition, an inorganic photosensitive composition has been envisioned and/or researched. The inorganic photosensitive composition is mainly utilized for negative tone patterning having resistance against removal by a developer composition due to chemical modification through a nonchemical amplification mechanism. The inorganic composition contains an inorganic element having a higher EUV absorption rate than hydrocarbons and thus may secure sensitivity through the nonchemical amplification mechanism and in addition, is less sensitive about a stochastic effect and thus may have low line edge roughness and smaller number of defects.

Inorganic photoresists based on peroxopolyacids of tungsten mixed with niobium, titanium, and/or tantalum have been reported as radiation sensitive materials for patterning.

These materials are effective for patterning large pitches for bilayer configuration as far ultraviolet (deep UV), X-ray, and electron beam sources. More recently, when cationic hafnium metal oxide sulfate (HfSOₓ) materials along with a peroxo complexing agent were utilized to image a 15 nm half-pitch (HP) through projection EUV exposure, impressive performance has been obtained. This system exhibits the highest performance of a non-CA photoresist and has a practicable photospeed close to the requirement for an EUV photoresist. However, the hafnium metal oxide sulfate materials having the peroxo complexing agent have a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of about 25 wt % and/or the like.

### SUMMARY

An aspect according to one or more embodiments is directed toward a semiconductor photoresist composition having improved storage stability and coating properties.

An aspect according to one or more embodiments is directed toward a method of forming patterns utilizing the semiconductor photoresist composition.

Recently, active research has been conducted on molecules containing tin, which may have excellent or suitable absorption of extreme ultraviolet rays. As for an organotin polymer, alkyl ligands are dissociated by light absorption or secondary electrons produced thereby, and are cross-linked with adjacent chains through oxo bonds and thus enable the negative tone patterning which may not be removed by an organic developing solution. This organotin polymer exhibits greatly improved sensitivity as well as maintains a resolution and line edge roughness, but the patterning characteristics need to be additionally improved for commercial application (e.g., availability).

A semiconductor photoresist composition according to one or more embodiments includes an organotin compound represented by Chemical Formula 1 and a solvent.

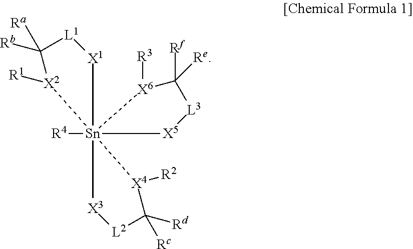

In Chemical Formula 1,

X¹ to X⁶ may each independently be O or S,

L¹ to L³ may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group having at least one double bond or triple bond, a substituted or unsubstituted divalent C6 to C20 aromatic hydrocarbon group, —C(=O)—, or a combination thereof,

R^{a}, R^{b}, R^{c}, R^{d}, R^{e}, R^{f}, and R¹ to R³ may each independently be hydrogen, a halogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and

R⁴ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof.

In an embodiment, R⁴ may be a substituted or unsubstituted C3 to C20 branched alkyl group.

In an embodiment, R¹ to R³ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, or a combination thereof.

In an embodiment, R¹ to R³ may each independently be an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

In an embodiment, L¹ to L³ may each independently be a single bond, or a substituted or unsubstituted C1 to C20 alkylene group.

In an embodiment, R^{a}, R^{b}, R^{c}, R^{d}, R^{e}, and R^{f} may each independently be hydrogen, a halogen, or a substituted or unsubstituted C1 to C10 alkyl group.

In an embodiment, each of X², X⁴, and X⁶ may be O.

In an embodiment, each of X¹ to X⁶ may be O.

In an embodiment, the organotin compound may be one selected from compounds listed in Group 1.

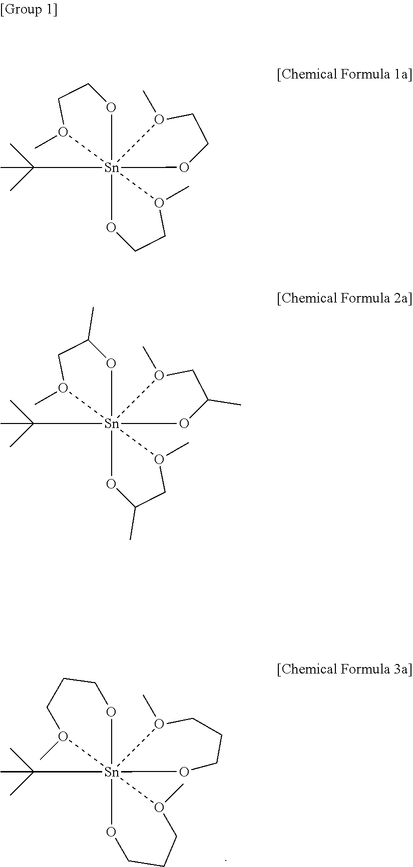

In an embodiment, the organotin compound may be included at about 1 wt % to about 30 wt % in amount based on 100 wt % of the semiconductor photoresist composition.

In an embodiment, the semiconductor photoresist composition may further include a surfactant, a crosslinking agent, a leveling agent, or a combination thereof.

A method of forming patterns according to one or more embodiments includes applying an etching-objective layer on a substrate, coating the semiconductor photoresist composition on the etching-objective layer to form a photoresist layer, patterning the photoresist layer to form a photoresist pattern, and etching the etching-objective layer utilizing the photoresist pattern as an etching mask.

In an embodiment, the photoresist pattern may be patterned or formed utilizing light in a wavelength of about 5 nm to about 150 nm.

In an embodiment, the method of forming patterns may further include providing a resist underlayer between the substrate and the photoresist layer.

In an embodiment, the photoresist pattern may have a width of about 5 nm to about 100 nm.

The semiconductor photoresist composition according to an embodiment may provide a photoresist pattern with improved sensitivity while maintaining suitable line edge roughness.

### BRIEF DESCRIPTION OF THE DRAWINGS

FIGS. 1-5 are each a cross-sectional view for explaining a method of forming patterns utilizing a semiconductor photoresist composition according to an embodiment.

### DETAILED DESCRIPTION

Hereinafter, referring to the drawings, embodiments of the present disclosure are described in more detail. In the following description of the present disclosure, the known functions or constructions will not be described in order to clarify the present disclosure.

In order to clearly illustrate the present disclosure, throughout the disclosure, the same or similar configuration elements are designated by the same reference numerals. Also, because the size and thickness of each configuration shown in the drawings are arbitrarily shown for better understanding and ease of description, the present disclosure is not necessarily limited thereto.

In the drawings, the thickness of layers, films, panels, regions, etc., are exaggerated for clarity. In the drawings, the thickness of a part of layers or regions, etc., is exaggerated for clarity. It will be understood that when an element such as a layer, film, region, or substrate is referred to as being “on” another element, it can be directly on the other element or intervening elements may also be present.

As used herein, the term “substituted” refers to replacement of a hydrogen atom by deuterium, a halogen, a hydroxy group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof. The term “unsubstituted” refers to non-replacement of a hydrogen atom by another substituent and remaining as the hydrogen atom.

As used herein, when a definition is not otherwise provided, “an alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, a C1 to C5 alkyl group, or a C1 to C4 alkyl group. For example, the C1 to C4 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, when a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but the present disclosure is not limited thereto.

As used herein, the term “aryl group” refers to a substituent in which all atoms in the cyclic substituent have a p-orbital and these p-orbitals are conjugated and may include a monocyclic or fused ring polycyclic (i.e., rings sharing adjacent pairs of carbon atoms) functional group.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

In the chemical formulas described herein, the term “t-Bu” refers to a tert-butyl group.

Hereinafter, a semiconductor photoresist composition according to an embodiment is described in more detail.

The semiconductor photoresist composition according to an embodiment of the present disclosure includes an organotin compound represented by Chemical Formula 1 and a solvent.

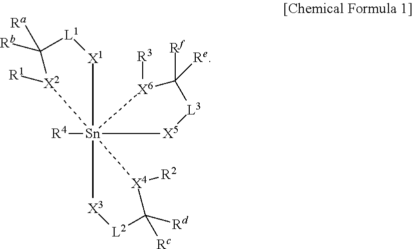

In Chemical Formula 1,

X¹ to X⁶ may each independently be O or S,

L¹ to L³ may each independently be a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group having at least one double bond or triple bond, a substituted or unsubstituted divalent C6 to C20 aromatic hydrocarbon group, —C(═O)—, or a combination thereof,

R^{a}, R^{b}, R^{c}, R^{d}, R^{e}, R^{f}, and R¹ to R³ may each independently be hydrogen, a halogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and

R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof.

Because the organotin compound has two or more coordination sites in addition to the O and/or S directly bonded to Sn, intramolecular as well as intermolecular coordination bonds are induced due to the unshared electron pairs of O and/or S, which is desirable (e.g., advantageous) for formation of an amorphous matrix.

For example, compared with a tetravalently coordinated cluster, because in the organotin compound according to one or more embodiments, the additional coordination bonds satisfy the coordination number of Sn and Sn is structurally covered, stability to moisture may be improved, and in addition, long-term storage stability may be enhanced by preventing or reducing aggregation due to nucleation caused by oxygen in the cluster. Accordingly, defects in the coating process are effectively reduced, which can affect coating stability.

In addition, compared to a monomolecular form, in the organotin compound according to one or more embodiments, intermolecular and/or intramolecular bonding is improved, resulting in improved binding force with the substrate, and thus improving thin film stability.

In addition, in the organotin compound according to one or more embodiments, because aggregation caused by nucleation is prevented or reduced, spin coating may be performed in an amorphous form without utilizing additives, and thus sensitivity and coating properties may be improved.

For example, R⁴ may be a substituted or unsubstituted C3 to C20 branched alkyl group.

The branched alkyl group refers to a form in which the metal-bonded carbon atom is a secondary carbon, a tertiary carbon, or a quaternary carbon, and may be an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

For example, R¹ to R³ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, or a combination thereof.

In an embodiment, R¹ to R³ may each independently be an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

For example, L¹ to L³ may each independently be a single bond, or a substituted or unsubstituted C1 to C20 alkylene group.

In an embodiment, L¹ to L³ may each independently be a single bond, or a substituted or unsubstituted C1 to C10 alkylene group.

For example, L¹ to L³ may each independently be a single bond, or a substituted or unsubstituted C1 to C5 alkylene group.

In an embodiment, L¹ to L³ may each independently be a single bond, a substituted or unsubstituted methylene group, a substituted or unsubstituted ethylene group, or a substituted or unsubstituted propylene group.

For example, R^{a}, R^{b}, R^{c}, R^{d}, R^{e}, and R^{f} may each independently be hydrogen, a halogen, or a substituted or unsubstituted C1 to C10 alkyl group.

In an embodiment, R^{a}, R^{b}, R^{c}, R^{d}, R^{e}, and R^{f} may each independently be hydrogen or a substituted or unsubstituted C1 to C5 alkyl group.

For example, R^{a}, R^{b}, R^{c}, R^{d}, R^{e}, and R^{f} may each independently be hydrogen, a methyl group, an ethyl group, an n-propyl group, or an n-butyl group.

For example, each of X², X⁴, and X⁶ may be O.

For example, each of X¹ to X⁶ may be O.

Non-limiting examples of the organotin compound may include compounds listed in Group 1.

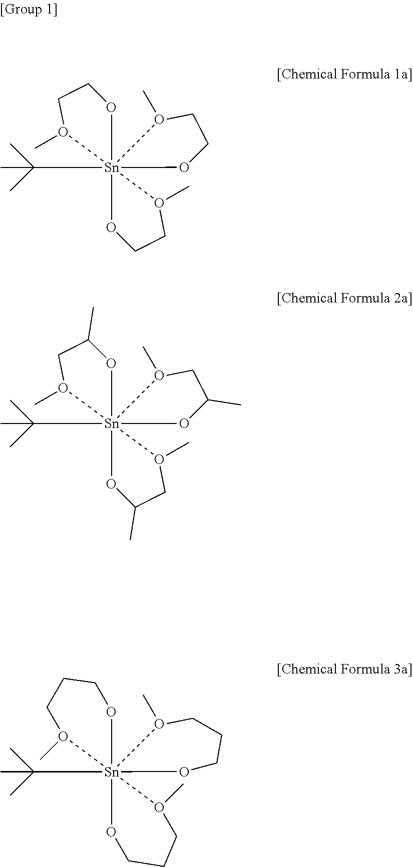

The organotin compound may suitably or strongly absorb extreme ultraviolet light at about 13.5 nm and may have excellent or suitable sensitivity to light having high energy.

In the semiconductor photoresist composition according to an embodiment, based on 100 wt % of the semiconductor photoresist composition, the organotin compound may be included in an amount of about 1 wt % to about 30 wt %, for example, about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, or for example, about 1 wt % to about 5 wt %, but the amount thereof is not limited thereto. When the organotin compound is included in an amount within the above ranges, storage stability and etch resistance of the semiconductor photoresist composition are improved, and resolution characteristics are improved.

As the semiconductor photoresist composition according to an embodiment of the present disclosure includes the aforementioned organotin compound, the semiconductor photoresist composition may have excellent or suitable sensitivity and pattern-forming ability.

The solvent included in the semiconductor resist composition according to an embodiment may be an organic solvent, and for example, one or more aromatic compounds (e.g., xylene, toluene, etc.), alcohols (e.g., 4-methyl-2-pentenol, 4-methyl-2-propanol, 1-butanol, methanol, isopropyl alcohol, 1-propanol, etc.), ethers (e.g., anisole, tetrahydrofuran, etc.), esters (n-butyl acetate, propylene glycol monomethyl ether acetate, ethyl acetate, ethyl lactate, etc.), ketones (e.g., methyl ethyl ketone, 2-heptanone, etc.), or a mixture thereof, but the present disclosure is not limited thereto.

In an embodiment, the semiconductor resist composition may further include a resin in addition to the organotin compound and the solvent.

The resin may be a phenolic resin including at least one of the aromatic moieties listed in Group 2.

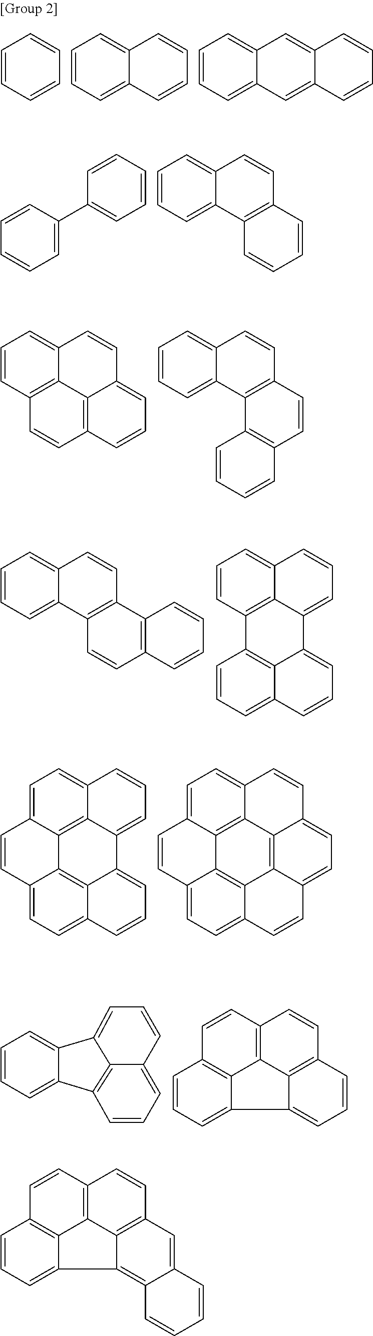

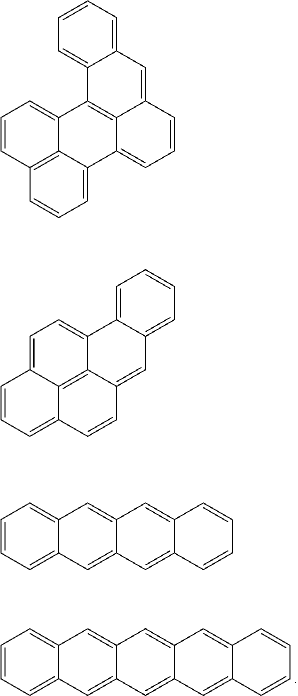

The resin may have a weight average molecular weight of about 500 to about 20,000.

The resin may be included in an amount of about 0.1 wt % to about 50 wt % based on a total amount of the semiconductor resist composition.

When the resin is included within the amount range, it may have excellent or suitable etch resistance and heat resistance.

According to an embodiment, the semiconductor resist composition is desirably composed of the aforementioned organotin compound, a solvent, and a resin. However, the semiconductor resist composition according to the above embodiment may further include an additive as needed. Examples of the additive may include a surfactant, a crosslinking agent, a leveling agent, an organic acid, a quencher, or a combination thereof.

The surfactant may include, for example, an alkyl benzene sulfonate salt, an alkyl pyridinium salt, polyethylene glycol, a quaternary ammonium salt, or a combination thereof, but the present disclosure is not limited thereto.

The crosslinking agent may be, for example, a melamine-based crosslinking agent, a substituted urea-based crosslinking agent, an acryl-based crosslinking agent, an epoxy-based crosslinking agent, and/or a polymer-based crosslinking agent, but the present disclosure is not limited thereto. The crosslinking agent may have at least two crosslinking-forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be utilized for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but the present disclosure is not limited thereto.

The quencher may be diphenyl(p-tolyl) amine, methyl diphenyl amine, triphenyl amine, phenylenediamine, naphthylamine, diaminonaphthalene, or a combination thereof.

An amount of the additives may be suitably or easily adjusted according to desired or suitable physical properties and in some embodiments, the additives may not be provided.

In some embodiments, the semiconductor resist composition may further include a silane coupling agent as an adherence enhancer in order to improve a close-contacting force with the substrate (e.g., in order to improve adherence of the semiconductor resist composition to the substrate). The silane coupling agent may be, for example, a silane compound including a carbon-carbon unsaturated bond such as vinyltrimethoxysilane, vinyltriethoxysilane, vinyl trichlorosilane, and/or vinyltris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, and/or 3-methacryloxypropylmethyl diethoxysilane; trimethoxy[3-(phenylamino)propyl]silane, and/or the like, but the present disclosure is not limited thereto.

The semiconductor photoresist composition may be formed into a pattern having a high aspect ratio without collapsing. Accordingly, in order to form or pattern a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, or about 5 nm to about 20 nm, the semiconductor photoresist composition may be utilized for a photoresist process utilizing light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to an embodiment may be utilized to realize extreme ultraviolet lithography utilizing an EUV light source with a wavelength of about 13.5 nm.

According to another embodiment, a method of forming patterns utilizing the aforementioned semiconductor photoresist composition is provided. For example, the manufactured pattern may be a photoresist pattern.

The method of forming patterns according to an embodiment includes forming an etching-objective layer on a substrate, coating the semiconductor photoresist composition on the etching-objective layer to form a photoresist layer, patterning the photoresist layer to form a photoresist pattern, and etching the etching-objective layer utilizing the photoresist pattern as an etching mask.

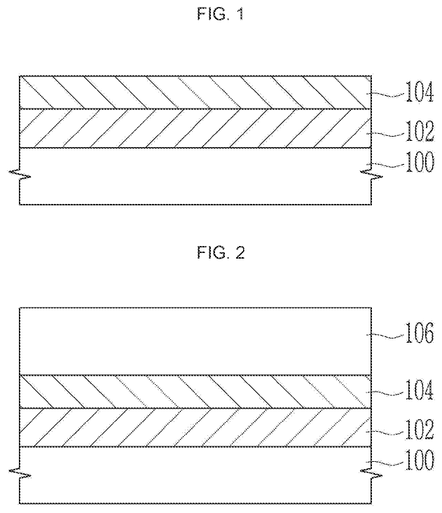

Hereinafter, a method of forming patterns utilizing the semiconductor photoresist composition is described in more detail by referring to FIGS. 1 to 5. FIGS. 1 to 5 are cross-sectional views for explaining a method of forming patterns utilizing a semiconductor photoresist composition according to an embodiment.

Referring to FIG. 1, an object for etching is prepared. The object for etching may be a thin film 102 formed on a semiconductor substrate 100. Hereinafter, the thin film 102 is described as the object for etching for convenience. A whole surface of the thin film 102 is washed to remove impurities and/or the like remaining thereon. The thin film 102 may be, for example, a silicon nitride layer, a polysilicon layer, or a silicon oxide layer.

Subsequently, the resist underlayer composition for forming a resist underlayer 104 is spin-coated on the surface of the washed thin film 102. However, the embodiment is not limited thereto, and one or more suitable coating methods, for example a spray coating, a dip coating, a knife edge coating, a printing method (for example an inkjet printing and/or a screen printing), and/or the like may be utilized.

The coating process of the resist underlayer may not be provided in more detail, and hereinafter, a process including a coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and improve pattern-forming ability of a photoresist line width when a ray reflected from the interface between the substrate 100 and the photoresist layer 106 or a hardmask between layers is scattered into an unintended photoresist region.

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

For example, the formation of a pattern by utilizing the semiconductor photoresist composition may include coating the aforementioned semiconductor resist composition on the substrate 100 having the thin film 102 through spin coating, slit coating, inkjet printing, and/or the like and then, drying it to form the photoresist layer 106.

The semiconductor photoresist composition has already been described in detail and will not be illustrated again.

Subsequently, the substrate 100 having the photoresist layer 106 is subjected to a first baking process. The first baking process may be performed at about 80° C. to about 120° C.

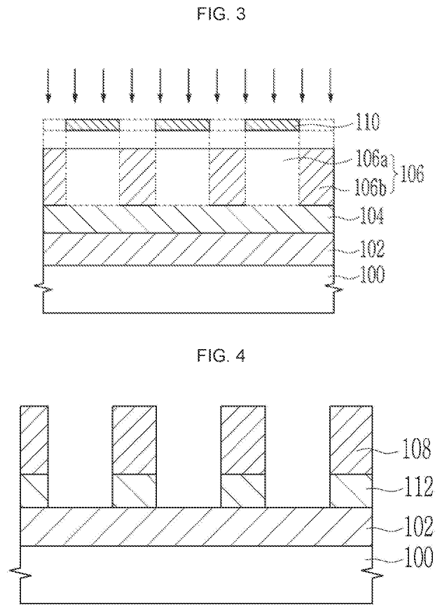

Referring to FIG. 3, the photoresist layer 106 may be selectively exposed.

For example, the exposure may utilize an activation radiation with light having a high energy wavelength such as EUV (extreme ultraviolet; a wavelength of about 13.5 nm), an E-Beam (an electron beam), and/or the like as well as a short wavelength such as an i-line (a wavelength of about 365 nm), a KrF excimer laser (a wavelength of about 248 nm), an ArF excimer laser (a wavelength of about 193 nm), and/or the like.

In an embodiment, light for the exposure according to an embodiment may have a short wavelength in a range of about 5 nm to about 150 nm and a high energy wavelength, for example, EUV (Extreme UltraViolet; a wavelength of about 13.5 nm), an E-Beam (an electron beam), and/or the like.

The exposed region 106b of the photoresist layer 106 has a different solubility from the non-exposed region 106a of the photoresist layer 106 by forming a polymer through a crosslinking reaction (such as condensation) between organometallic compounds.

Subsequently, the substrate 100 is subjected to a second baking process. The second baking process may be performed at a temperature of about 90° C. to about 200° C. The exposed region 106b of the photoresist layer 106 becomes indissoluble (e.g., not easily dissolvable) in a developing solution due to the second baking process.

In FIG. 4, the non-exposed region 106a of the photoresist layer is dissolved and removed utilizing the developing solution to form a photoresist pattern 108. For example, the non-exposed region 106a of the photoresist layer is dissolved and removed by utilizing an organic solvent such as 2-heptanone and/or the like to complete the photoresist pattern 108 corresponding to the negative tone image.

As described above, a developing solution utilized in a method of forming patterns according to an embodiment may be an organic solvent. The organic solvent utilized in the method of forming patterns according to an embodiment may be, for example, one or more ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to an embodiment is not necessarily limited to the negative tone image but may be formed to have a positive tone image. Herein, a developing agent utilized for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (Extreme UltraViolet; a wavelength of about 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width (e.g., width of a thickness) of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

On the other hand, the photoresist pattern 108 may have a pitch with a half-pitch of less than or equal to about 50 nm, for example, less than or equal to about 40 nm, for example, less than or equal to about 30 nm, for example, less than or equal to about 20 nm, or for example, less than or equal to about 15 nm and a line width roughness of less than or equal to about 10 nm, less than or equal to about 5 nm, less than or equal to about 3 nm, or less than or equal to about 2 nm.

Subsequently, the photoresist pattern 108 is utilized as an etching mask to etch the resist underlayer 104. Through this etching process, an organic layer pattern 112 is formed. The organic layer pattern 112 also may have a width corresponding to that of the photoresist pattern 108.

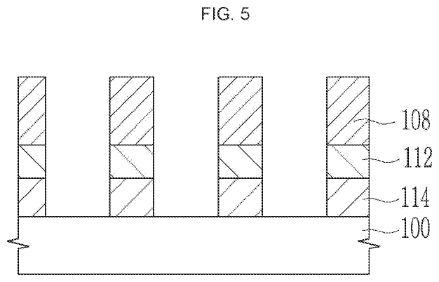

Referring to FIG. 5, the photoresist pattern 108 is applied as an etching mask to etch the exposed thin film 102. As a result, the thin film is formed with a thin film pattern 114.

The etching of the thin film 102 may be, for example, dry etching utilizing an etching gas and the etching gas may be, for example, CHF₃, CF₄, Cl₂, BCl₃, or a mixed gas thereof.

In the exposure process, the thin film pattern 114 formed by utilizing the photoresist pattern 108 formed through the exposure process performed by utilizing an EUV light source may have a width corresponding to that of the photoresist pattern 108. For example, the thin film pattern 114 may have a width of about 5 nm to about 100 nm, which is (e.g., substantially) equal to that of the photoresist pattern 108. For example, the thin film pattern 114 formed by utilizing the photoresist pattern 108 (formed through the exposure process performed by utilizing an EUV light source) may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or less than or equal to about 20 nm.

Hereinafter, the present disclosure will be described in more detail through examples of the preparation of the aforementioned semiconductor photoresist composition. However, the technical features of the present disclosure are not limited by the following examples.

### Synthesis of Organotin Compounds

### Synthesis Example 1

20 g (64.7 mmol) of tert-BuSn[N(CH₃)₂]₃ was dissolved in 200 mL of toluene in a 250 mL 2-necked and round-bottomed flask and then, cooled down to −20° C. in a dry ice bath. Subsequently, 14.8 g (200.0 mmol) of 2-methoxyethanol was slowly added in a dropwise fashion, and the temperature was gradually raised to room temperature. Thereafter, the resultant was refluxed at 120° C. for 6 hours to obtain a tert-BuSn(O(CH₂)₂OCH₃)₃ compound represented by Chemical Formula 1a.

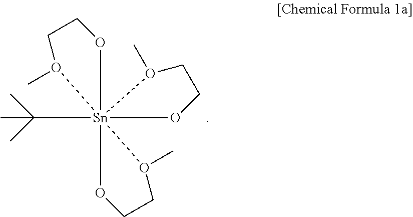

### Synthesis Example 2

A tert-BuSn(O(iPr)OCH₃)₃ compound represented by Chemical Formula 2a was obtained in substantially the same manner as in Synthesis Example 1, except that 18 g (200.0 mmol) of 1-methoxypropanol was utilized instead of 2-methoxyethanol.

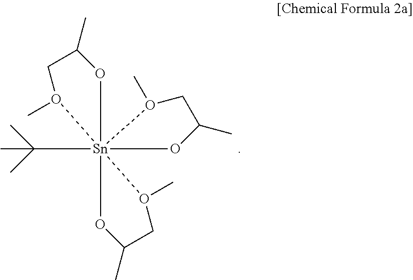

### Synthesis Example 3

A tert-BuSn(O(CH₂)₃OCH₃)₃ compound represented by Chemical Formula 3a was obtained in substantially the same manner as in Synthesis Example 1, except that 18 g (200.0 mmol) of 3-methoxypropanol was utilized instead of 2-methoxyethanol.

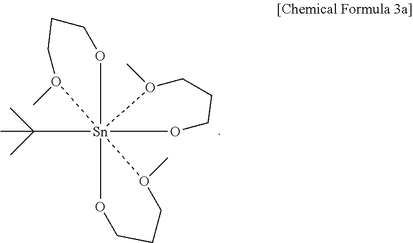

### Comparative Synthesis Example 1

20 g (51.9 mmol) of Ph₃SnCl was dissolved in 70 mL of THF in a 250 mL 2-necked and round-bottomed flask and then, cooled down to 0° C. in an ice bath. Subsequently, a 1 M butyl magnesium chloride (BuMgCl) THF solution (62.3 mmol) was slowly added thereto in a dropwise fashion. When the addition in a dropwise fashion was complete, the obtained mixture was stirred at 25° C. for 12 hours to obtain a BuSnPh₃ compound.

Then, BuSnPh₃ (10 g, 24.6 mmol) was dissolved in 50 mL of CH₂Cl₂, and 3 equivalents (73.7 mmol) of a 2 M HCl diethyl ether solution was slowly added thereto in a dropwise fashion at −78° C. for 30 minutes. Subsequently, the obtained mixture was stirred at 25° C. for 12 hours, and then, a BuSnCl₃ compound was obtained by concentrating the solvent and performing vacuum distillation.

Thereafter, 25 mL of propionic acid was slowly added in a dropwise fashion to 10 g (25.6 mmol) of the BuSnCl₃ compound at 25° C., followed by heating under reflux for 12 hours. The temperature was increased to 25° C., and then, acetic acid was vacuum-distilled to obtain a tert-BuSn(OCOC₂H₅)₃ compound.

### Comparative Synthesis Example 2

20 g (77 mmol) of SnCl₄ was dissolved in 100 ml of toluene in a 250 mL 2-necked round bottomed flask, and the temperature was lowered to −30° C. in a dry ice bath. Subsequently, 77 mmol of tBuLi (1.7 M pentane solution) was slowly added in a dropwise fashion, and the temperature was gradually raised to room temperature. Thereafter, the temperature was lowered to −30° C. again through a dry ice bath, and 17.4 g (220 mmol) of lithium diethylamide weighed in an argon atmosphere glove box was dissolved in THF and slowly decanted utilizing a PTFE cannula. The temperature was gradually raised to room temperature, and after stirring for 3 hr, the filtering was performed in an Ar atmosphere utilizing a fritted filter (G4). The solvent was removed utilizing vacuum to obtain tert-BuSn[N(C₂H₅)₂]₃ compound.

### Comparative Synthesis Example 3

A tert-BuSn(OC₂H₅)₃ compound was obtained in substantially the same manner as in Synthesis Example 1, except that 9.214 g (200.0 mmol) of ethanol was utilized instead of 2-methoxyethanol.

### Examples 1 to 5 and Comparative Examples 1 to 3: Preparation of Semiconductor Photoresist Compositions

Each compound obtained in Synthesis Examples 1 to 3 and Comparative Synthesis Examples 1 to 3 was dissolved at a concentration of 3 wt % in 1-methyl-2-propyl acetate in the weight ratio shown in Table 1 and the resultant was filtered through a 0.1 μm PTFE (polytetrafluoroethylene) syringe filter to prepare each semiconductor photoresist composition.

TABLE 1

| | Organometallic compound |
|---|---|
| Example 1 | Chemical Formula 1a |
| Example 2 | Chemical Formula 2a |
| Example 3 | Chemical Formula 3a |
| Example 4 | Chemical Formula 1a (100 parts by weight) + |
| | Chemical Formula 2a (40 parts by weight) |
| Example 5 | Chemical Formula 1a (100 parts by weight) + |
| | Chemical Formula 3a (40 parts by weight) |
| Comparative Example 1 | tert-BuSn(OCOC₂H₅)₃ |
| Comparative Example 2 | tert-BuSn[N(C₂H₅)₂]₃ |
| Comparative Example 3 | tert-BuSn(OC₂H₅)₃ |

### Formation of Photoresist Layer

A circular silicon wafer with a diameter of 8 inches and a native-oxide surface thereon was utilized as a substrate for deposition a thin film and treated in a UV ozone cleaning system for 10 minutes before depositing the thin film. On the treated substrate, each semiconductor photoresist composition according to Examples 1 to 5 and Comparative Examples 1 to 3 was spin-coated at 1500 rpm for 30 seconds and then, post-apply baked (PAB) at 160° C. for 60 seconds to form the thin film.

The thickness of each of the thin films was measured after the coating and the baking through ellipsometry, and the result was 25 nm for each of the thin films.

### Evaluation 1: Evaluation of Coating Properties

Each surface roughness (Rq value) of the photoresist films according to Examples 1 to 5 and Comparative Examples 1 to 3 prepared by the coating method was measured utilizing AFM (atomic force microscopy), and the results are shown in Table 2.

### Evaluation 2: Evaluation of Sensitivity and Line Edge Roughness (LER)

EUV light (Lawrence Berkeley National Laboratory Micro Exposure Tool, MET) was utilized to project a linear array of 50 circular pads with a diameter of 500 μm onto the wafer coated with each photoresist composition according to Examples 1 to 5 and Comparative Examples 1 to 3. Herein, pad exposure time was controlled or selected to apply an incremental EUV dose to each pad.

Subsequently, the resist and the substrate were post-exposure baked (PEB) on a hotplate at 160° C. for 120 seconds after the exposure. The baked film was dipped in a developing solution (2-heptanone) for 30 seconds and additionally, washed with the same developer for 10 seconds to form a negative tone image, that is, to remove a non-exposed coating region. Finally, the obtained film was baked on a hot plate at 150° C. for 2 minutes, thereby completing the process.

The residual resist thickness of the exposed pads were measured through ellipsometry. A residual thickness at each exposure dose was measured and graphed as a function of the exposure dose to obtain Dg (an energy level at which the development was completed) of each resist, and the results are shown in Table 2 as sensitivity (mJ/cm⁻¹).

The FE-SEM image was utilized to measure line edge roughness (LER) of the formed lines, and the results are shown in Table 2.

### Evaluation 3: Evaluation of Storage Stability

The photoresist compositions according to Examples 1 to 5 and Comparative Examples 1 to 3 were measured with respect to initial sensitivity and sensitivity after allowed to stand at room temperature (25° C.) for 4 weeks to evaluate storage stability according to the following formula.

Storage stability=[(initial sensitivity−sensitivity after being left for 4 weeks)/initial sensitivity]*100

TABLE 2

| | Coating | | | Storage |
|---|---|---|---|---|
| | properties | Sensitivity | LER | stability |
| | (Rq) | (mJ/cm⁻¹) | (nm) | (%) |
| Example 1 | 0.47 | 900 | 3.9 | 3.7 |
| Example 2 | 0.36 | 920 | 3.7 | 3.2 |
| Example 3 | 0.58 | 920 | 3.9 | 5.4 |
| Example 4 | 0.38 | 950 | 3.6 | 3.5 |
| Example 5 | 0.47 | 980 | 4.0 | 4.1 |
| Comparative Example 1 | 1.17 | 1,390 | 4.9 | 16.4 |
| Comparative Example 2 | 1.35 | 970 | 4.9 | 17.3 |
| Comparative Example 3 | 0.75 | 1,530 | 4.2 | 6.8 |

Referring to the results of Table 2, the photoresist compositions (each for a semiconductor) according to Examples 1 to 5 each exhibited excellent or suitable coating properties and storage stability, and patterns respectively formed therefrom exhibited excellent or suitable sensitivity without significantly increased line edge roughness, compared with patterns formed from the photoresist compositions (each for a semiconductor) according to Comparative Examples 1 to 3.

As used herein, the singular forms “a”, “an” and “the” are intended to include the plural forms as well, unless the context clearly indicates otherwise.

In addition, the term “layer” as used herein includes not only a shape formed on the whole surface when viewed from a plan view, but also a shape formed on a partial surface.

In the present specification, “at least one of A, B, or C”, “one of A, B, C, or a combination thereof” and even “one of A, B, C, and a combination thereof” (based on context) may each indicate only A, only B, only C, both (e.g., simultaneously) A and B, both (e.g., simultaneously) A and C, both (e.g., simultaneously) B and C, all of A, B, and C, or variations thereof.

As used herein, the term “or” is not to be construed as an exclusive meaning, for example, “A or B” is construed to include A, B, A+B, and/or the like.

Hereinafter, the term “combination” includes a mixture of two or more, a composite of two or more, a copolymer of two or more, an alloy of two or more, a blend of two or more, mutual substitution, and a laminated structure of two or more.

Hereinbefore, the certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Description of Symbols

| | |
|---|---|
| 100: substrate | 102: thin film |
| 104: resist underlayer | 106: photoresist layer |
| 106a: non-exposed region | 106b: exposed region |
| 108: photoresist pattern | 112: organic layer pattern |
| 110: patterned hardmask | 114: thin film pattern |

What is claimed is:

1. A semiconductor photoresist composition, comprising:
an organotin compound represented by Chemical Formula 1; and
a solvent: 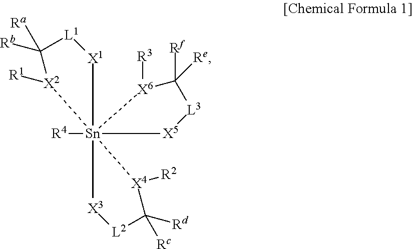
wherein, in Chemical Formula 1,
X¹ to X⁶ are each independently O or S,
L¹ to L³ are each independently a single bond, a substituted or unsubstituted divalent C1 to C20 saturated aliphatic hydrocarbon group, a substituted or unsubstituted divalent C3 to C20 saturated or unsaturated alicyclic hydrocarbon group, a substituted or unsubstituted divalent C2 to C20 unsaturated aliphatic hydrocarbon group having at least one double bond or triple bond, a substituted or unsubstituted divalent C6 to C20 aromatic hydrocarbon group, —C(═O)—, or a combination thereof,
R^{a}, R^{b}, R^{c}, R^{d}, R^{e}, R^{f}, and R¹ to R³ are each independently hydrogen, a halogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof, and
R⁴ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof.

2. The semiconductor photoresist composition of claim 1, wherein
R⁴ is a substituted or unsubstituted C3 to C20 branched alkyl group.

3. The semiconductor photoresist composition of claim 1, wherein
R¹ to R³ are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, or a combination thereof.

4. The semiconductor photoresist composition of claim 1, wherein
R¹ to R³ are each independently an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

5. The semiconductor photoresist composition of claim 1, wherein
L¹ to L³ are each independently a single bond, or a substituted or unsubstituted C1 to C20 alkylene group.

6. The semiconductor photoresist composition of claim 1, wherein
R^{a}, R^{b}, R^{c}, R^{d}, R^{e}, and R^{f} are each independently hydrogen, a halogen, or a substituted or unsubstituted C1 to C10 alkyl group.

7. The semiconductor photoresist composition of claim 1, wherein
each of X², X⁴ and X⁶ is O.

8. The semiconductor photoresist composition of claim 1, wherein
each of X¹ to X⁶ is O.

9. The semiconductor photoresist composition of claim 1, wherein
the organotin compound is selected from compounds listed in Group 1:

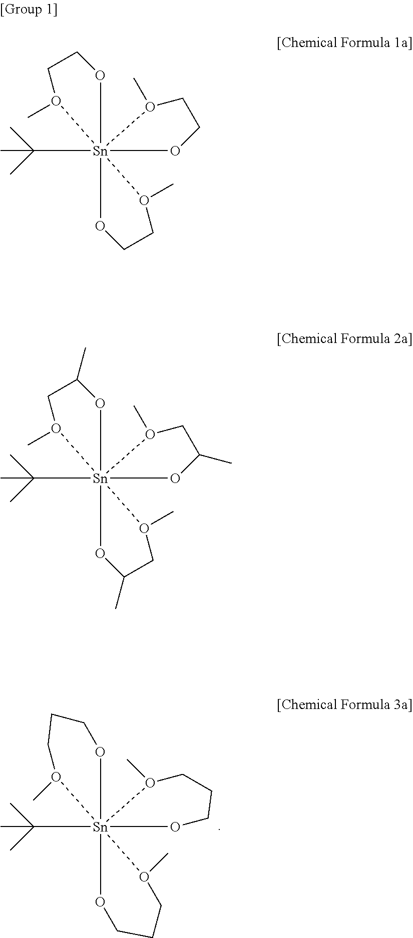

10. The semiconductor photoresist composition of claim 1, wherein
the organotin compound is included at about 1 wt % to about 30 wt % in amount based on 100 wt % of the semiconductor photoresist composition.

11. The semiconductor photoresist composition of claim 1, wherein
the semiconductor photoresist composition further comprises a surfactant, a crosslinking agent, a leveling agent, or a combination thereof.

12. A method of forming patterns, the method comprising:
applying an etching-objective layer on a substrate;
coating the semiconductor photoresist composition of claim 1 on the etching-objective layer to form a photoresist layer;
patterning the photoresist layer to form a photoresist pattern; and
etching the etching-objective layer utilizing the photoresist pattern as an etching mask.

13. The method of claim 12, wherein
the photoresist pattern is patterned utilizing light in a wavelength of about 5 nm to about 150 nm.

14. The method of claim 12, wherein
the method further comprises providing a resist underlayer between the substrate and the photoresist layer.

15. The method of claim 12, wherein
the photoresist pattern has a width of about 5 nm to about 100 nm.
